(19) United States
(12) Patent Application Publication
(10) Pub. No.: US 2019/0148210 A1
(43) Pub. Date: May 16, 2019

(54) SUBSTRATE TRANSFER HAND AND ROBOT

(71) Applicant: KAWASAKI JUKOGYO KABUSHIKI KAISHA, Kobe-shi, Hyogo (JP)

(72) Inventor: Takeshi SHIBATA, Akashi-shi (JP)

(73) Assignee: KAWASAKI JUKOGYO KABUSHIKI KAISHA, Kobe-shi, Hyogo (JP)

(21) Appl. No.: 16/088,389

(22) PCT Filed: Mar. 1, 2017
(86) PCT No.: PCT/JP2017/008143

§ 371 Date: Sep. 25, 2018

(30) Foreign Application Priority Data
Mar. 25, 2016 (JP) 2016-062130

(51) Int. Cl. H01L 21/687; B25J 15/00; H01L 21/677

(52) U.S. Cl. CPC H01L 21/68707; H01L 21/67766; B25J 15/0033

(57) ABSTRACT

A substrate transfer hand has a casing; blade; front guide provided at a blade tip end portion with first and second support parts being different in height from the blade; first rear guide at the blade base end portion, and having a portion with a height from the blade that is equal to a height from the blade, of the first support part of the front guide; second rear guide at a base end side of the blade, and having a portion with a height from the blade that is equal to a height from the blade, of the second support part of the front guide; and driving device inside the casing with an advanceable and retractable output end and moves the second rear guide coupled to the output end within a region where the second rear guide does not overlap the blade in a blade normal direction.

### TECHNICAL FIELD

The present invention relates to a substrate transfer hand which holds and transfers a substrate such as a semiconductor wafer or a glass substrate, and a robot including the substrate transfer hand.

### BACKGROUND ART

A transfer robot which transfers a substrate such as a semiconductor wafer or a glass substrate includes an end effector, for example, a hand, at a tip end portion thereof. By this hand, the substrate is held and transferred. As an example of the hand which holds the substrate, there is an edge grip hand which grips the substrate. In a semiconductor process, such as a substrate cleaning process, there is sometimes a case where a contaminated substrate which is to be subjected to cleaning and a clean substrate which has been subjected to the cleaning co-exist in the same process. In this case, if the substrate is transferred by one hand of the transfer robot, the hand is contaminated by the contaminated substrate and the clean substrate held by the contaminated hand is contaminated. Patent Literature 1 discloses an example of a hand which is capable of preventing the contamination of the substrate.

The hand disclosed in Patent literature 1 includes two sets of plural gripping elements (e.g., see FIG. 10) for holding the substrate. In the hand disclosed in Patent Literature 1, one of the two sets of gripping elements are used to grip the contaminated substrate, and the other set of gripping elements are used to grip the clean substrate. In this way, the above-described contamination of the substrate is prevented.

### CITATION LIST

### Patent Literature

Patent Literature 1: Japanese-Laid Open Patent Application Publication No. 2007-067345

### SUMMARY OF INVENTION

### Technical Problem

In the hand disclosed in Patent Literature 1, the substrate to be gripped by one of the two sets of plural gripping elements is located slightly higher than the substrate to be gripped by the other set of plural gripping elements. Patent Literature 1 is directed to providing a thin and compact workpiece gripping device with a pine-needle shape, by configuring the hand as described above.

In the hand disclosed in Patent Literature 1, a metal belt extending from the base end side of the blade to the tip end side of the blade is used as a driving force transmission member which slides the gripping elements provided at the tip end portion of the blade. In a case where a hollow part into which the metal belt is inserted is provided at the blade, the strength of the blade is reduced due to this hollow part. The blade is a thin plate member. If flexure of the blade easily occurs due to a reduced strength, the stability of the operation of the hand may be degraded.

In view of the above-described circumstances, an object of the present invention is to provide a substrate transfer hand which includes plural sets of substrate support parts in a single blade and can realize a stable operation, and a robot including this substrate transfer hand.

### Solution to Problem

According to one aspect of the present invention, a substrate transfer hand comprises a casing; a blade with a thin plate shape, the blade having a base end portion coupled to the casing; a front guide provided at a tip end portion of the blade, and including a first support part and a second support part which support a substrate, the first support part and the second support part being different in height from the blade; a first rear guide provided at the base end portion of the blade, and having a portion with a height from the blade that is equal to a height from the blade, of the first support part of the front guide; a second rear guide provided at a base end side of the blade, and having a portion with a height from the blade that is equal to a height from the blade, of the second support part of the front guide; and a driving device provided inside the casing, and having an output end which is advanceable and retractable with respect to the substrate supported by the blade, the driving device being configured to move the second rear guide coupled to the output end within a region where the second rear guide does not overlap with the blade in a normal direction of the blade. The “normal direction of the blade” is defined as a direction perpendicular to a primary surface of the blade and a direction parallel to the direction perpendicular to the primary surface of the blade.

According to one aspect of the present invention, a robot comprises an arm, and the above-described substrate transfer hand mounted on a tip end portion of the arm.

In the substrate transfer hand and the robot including the substrate transfer hand, described above, the second rear guide provided at the base end side of the blade is advanceable and retractable with respect to the substrate supported by the blade, and the driving device for driving the second rear guide is accommodated in the casing. In brief, the second rear guide and the driving device are disposed collectively at the base end portion of the hand. Since the second rear guide is movable within the region where the second rear guide does not overlap with the blade in the normal direction of the blade, the second rear guide and the driving device can be disposed while avoiding interference with the blade. This makes it possible to avoid reduction of a strength of the blade which would be caused by providing the second rear guide and the driving device, and maintain stability of the operation of the hand.

### Advantageous Effects of Invention

In accordance with the present invention, it is possible to provide a substrate transfer hand which includes plural sets of substrate support parts in a single blade and can realize a stable operation, and a robot including this substrate transfer hand.

### BRIEF DESCRIPTION OF DRAWINGS

FIG. 1 is a perspective view showing a transfer robot including a substrate transfer hand according to one embodiment of the present invention.

FIG. 2 is an enlarged plan view of the substrate transfer hand.

FIG. 3 is a schematic side view of the substrate transfer hand of FIG. 2.

FIG. 4 is a block diagram showing the configuration of a driving system of the substrate transfer hand of FIG. 2.

FIG. 5 is a side view of a front guide.

FIG. 6 is a view taken in the direction of arrows along line VI-VI of FIG. 2.

FIG. 7 is a plan view showing a state of the substrate transfer hand gripping a lower wafer.

FIG. 8 is a side view showing a state of the substrate transfer hand gripping the lower wafer.

FIG. 9 is a plan view showing a state of the substrate transfer hand supporting an upper wafer.

FIG. 10 is a side view showing a state of the substrate transfer hand supporting the upper wafer.

FIG. 11 is a plan view showing a state of the substrate transfer hand gripping the upper wafer.

FIG. 12 is a side view showing a state of the substrate transfer hand gripping the upper wafer.

FIG. 13 is a view for explaining a stroke of a lower pusher and a stroke of an upper pusher.

FIG. 14 is an enlarged plan view of a substrate transfer hand according to Modified Example 1.

FIG. 15 is a view taken in the direction of arrows along line XV-XV of FIG. 14.

FIG. 16 is a plan view showing a state in which the substrate transfer hand of FIG. 14 is gripping the lower wafer.

FIG. 17 is a plan view showing a state in which the substrate transfer hand of FIG. 14 is gripping the upper wafer.

FIG. 18 is an enlarged plan view of a substrate transfer hand according to Modified Example 2.

FIG. 19 is a view taken in the direction of arrows along line XIX-XIX of FIG. 18.

FIG. 20 is a plan view showing a state in which the substrate transfer hand of FIG. 18 is gripping the upper wafer.

### DESCRIPTION OF EMBODIMENTS

Hereinafter, the embodiments of the present invention will be described with reference to the drawings.

[Configuration of Transfer Robot 2]

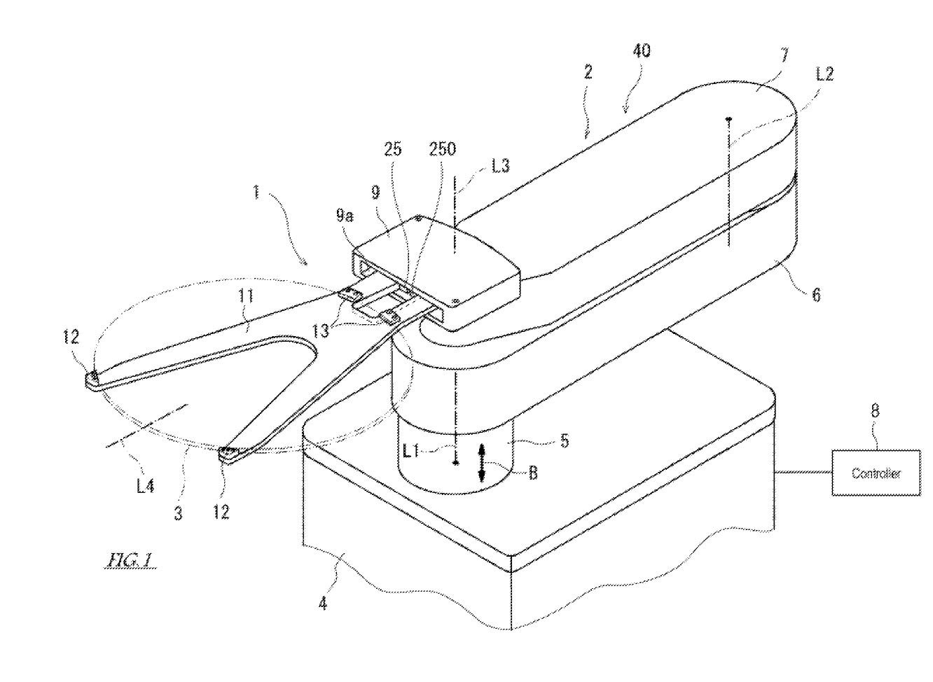

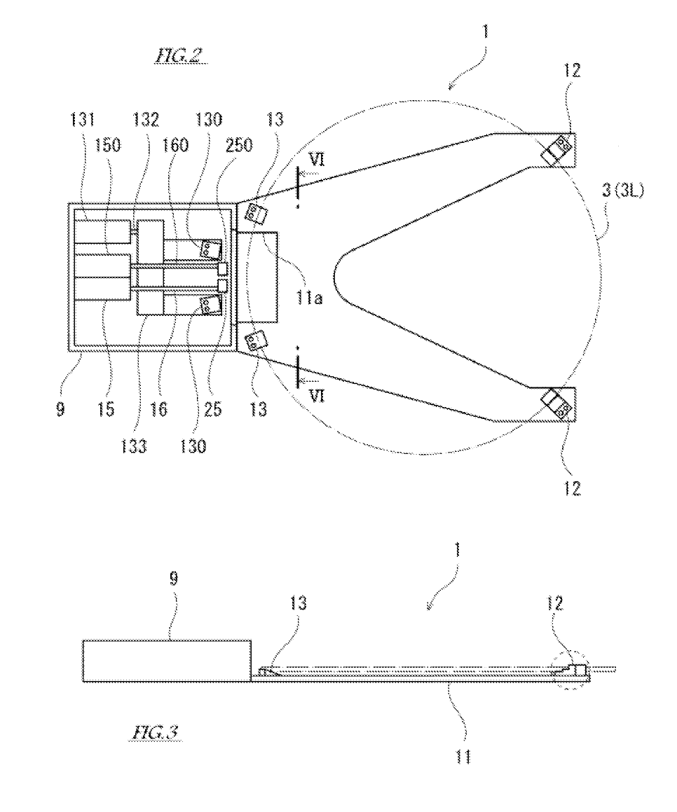

Initially, the basic configuration of a transfer robot 2 including a substrate transfer hand 1 according to one embodiment of the present invention will be described with reference to FIGS. 1 and 2. FIG. 1 is a perspective view showing the transfer robot 2 including the substrate transfer hand 1 according to one embodiment of the present invention. FIG. 2 is an enlarged plan view of the substrate transfer hand 1. Hereinafter, it is assumed that a side where a substrate 3 is placed in a state in which a blade 11 is made horizontal is an “upper” side and a side which is opposite to the upper side is a “lower” side. Also, a tip end side of the substrate transfer hand 1, from the perspective of the substrate transfer hand 1, is a “front (forward)” side and a side which is opposite to the front (forward) side is a “rear (rearward)” side.

The transfer robot 2 is a robot which transfers the substrate 3. For example, the transfer robot 2 is equipped in semiconductor treatment (processing) equipment. The substrate 3 is a thin plate used in a semiconductor process or the like. For example, the substrate includes a semiconductor wafer, a glass wafer, a sapphire (single crystal alumina) wafer, or the like. For example, the semiconductor wafer includes a silicon wafer, a semiconductor single body wafer other than silicon, a compound semiconductor wafer, or the like. The glass wafer includes a glass substrate for FPD (Flat Panel Display), a glass substrate for MEMS (Micro Electro Mechanical Systems). Hereinafter, as an example, the transfer robot 2 which transfers the wafer for the semiconductor process, which is one kind of the substrate, will be described.

The semiconductor treatment equipment includes semiconductor treatment devices (not shown) for performing process treatments such as a thermal treatment, an impurity implantation treatment, a thin film forming treatment, a lithography treatment, a cleaning treatment, and a flattening treatment. The transfer robot 2 is configured to hold a semiconductor process wafer (substrate 3) stored in a FOUP (not shown) and to transfer the wafer to a predetermined storage position within each of the semiconductor treatment devices. In addition, the transfer robot 2 is configured to hold the substrate 3 placed in the predetermined storage position within each of the semiconductor treatment devices, and to transfer this substrate 3 to the inside of another semiconductor treatment device.

The transfer robot 2 is a horizontal articulated three-axis robot. The transfer robot 2 includes a base 4 secured onto a casing of the semiconductor treatment equipment, an arm 40 supported by the base 4, and the substrate transfer hand 1 mounted on the tip end portion of the arm 40.

The base 4 is provided with an up-down shaft 5 which is movable up and down in a vertical direction (arrow B of FIG. 1). The up-down shaft 5 is configured to be movable up and down by an electric motor (not shown). A first link 6 is mounted on the upper end portion of the up-down shaft 5 which is movable up and down in this way. The first link 6 is an elongated member extending in a horizontal direction. The lengthwise first end portion of the first link 6 is mounted on the up-down shaft 5 so that the first link 6 is rotatable around a vertical axis L1. The first link 6 is driven to rotate by an electric motor which is not shown. A second link 7 is mounted on the lengthwise second end portion of the first link 6. The second link 7 is also an elongated member extending in the horizontal direction. The lengthwise first end portion of the second link 7 is mounted on the first link 6 so that the second link 7 is rotatable around a vertical axis L2. The second link 7 is driven to rotate by an electric motor which is not shown. The up-down shaft 5, the first link 6, the second link 7, and the like constitute the arm 40.

The base end portion of the substrate transfer hand 1 is mounted on the lengthwise second end portion of the second link 7 so that the substrate transfer hand 1 is rotatable around a vertical axis L3. The substrate transfer hand 1 is driven to rotate by an electric motor which is not shown. The up-down movement of the up-down shaft 5, the rotation of the first link 6, the rotation of the second link 7, and the rotation of the substrate transfer hand 1 are controlled by a controller 8 which will be described later.

[Schematic Configuration of Substrate Transfer Hand 1]

The substrate transfer hand 1 is configured to grip and hold the substrate 3. The substrate transfer hand 1 includes a casing 9 at its base end portion. The casing 9 is a hollow box (housing) member with a rectangular shape. The lower surface of the casing 9 is attached on the second link 7. The casing 9 has an opening 9a in a side surface facing the tip end of the substrate transfer hand 1.

The base end portion of the blade 11 is secured to the opening 9a of the casing 9. The blade 11 has forked (branched) portions at its tip end side. The blade 11 is a thin plate member with a Y-shape when viewed from a normal direction of the blade 11 (hereinafter will be referred to as “blade normal direction”). The blade normal direction is defined as a direction perpendicular to a primary (main) surface of the blade 11 and a direction parallel to the direction perpendicular to the primary surface of the blade 11. In a case where the blade 11 is horizontal, the blade normal direction conforms to a vertical direction.

A pair of front guides 12 are provided at the tip end portions, respectively, of the forked portions of the blade 11. Two pairs of rear guides 13, 130 are provided at the base end side of the blade 11 and face the pair of front guides 12. The pair of front guides 12, the pair of rear guides 13, and the pair of rear guides 130 are capable of supporting the substrate 3. To this end, the pair of front guides 12, the pair of rear guides 13, and the pair of rear guides 130 are positioned and have shapes so that the substrate 3 which is varied in shape can be properly supported by these guides. The shape of the substrate 3 is arbitrary. Hereinafter, a case where the substrate 3 has a circular shape will be described.

Further, the substrate transfer hand 1 is provided with pushers 25, 250, at the base end side of the blade 11. The pushers 25, 250 are advanceable and retractable in parallel with a center line L4 of the blade 11. Driving mechanisms (cylinders 15, 150 (see FIG. 3)) for the pushers 25, 250 are accommodated in the casing 9. Each of the pushers 25, 250 is configured to push the substrate 3 supported on the upper surface of the blade 11 by the rear guides 13 or 130 and the pair of front guides 12, to the pair of front guides 12. In this way, the substrate 3 is gripped by the pusher 25 or 250 and the pair of front guides 12.

The transfer robot 2 includes the controller 8. The controller 8 is connected to the electric motor (not shown) which moves the up-down shaft 5 up and down, and the electric motors (not shown) which rotate the first link 6, the second link 7, and the substrate transfer hand 1. The controller 8 is configured to control each of the electric motors based on a predetermined program. As will be described later, the controller 8 is connected to the driving mechanisms for the upper rear guides 130, the lower pusher 25, and the pusher 250 and configured to control the operations of these driving mechanisms.

The transfer robot 2 controlled by the controller 8 with the above-described configuration is configured to perform operations for moving the substrate transfer hand 1 to a desired position, gripping the substrate 3 by the substrate transfer hand 1, and releasing the gripped substrate 3, by the up-down movement of the up-down shaft 5 and the rotations of the first link 6, the second link 7, and the substrate transfer hand 1.

[Configuration of Substrate Transfer Hand 1]

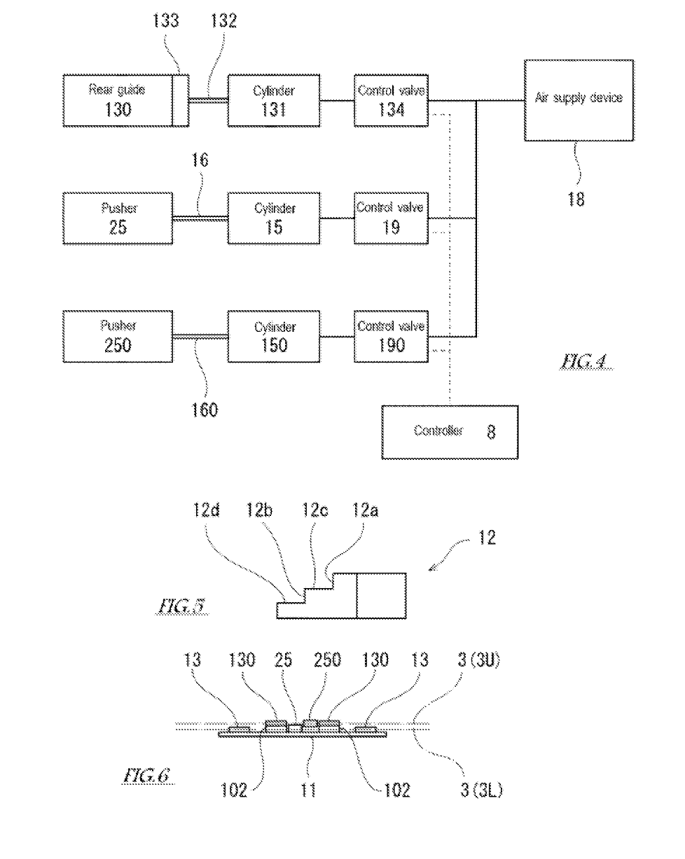

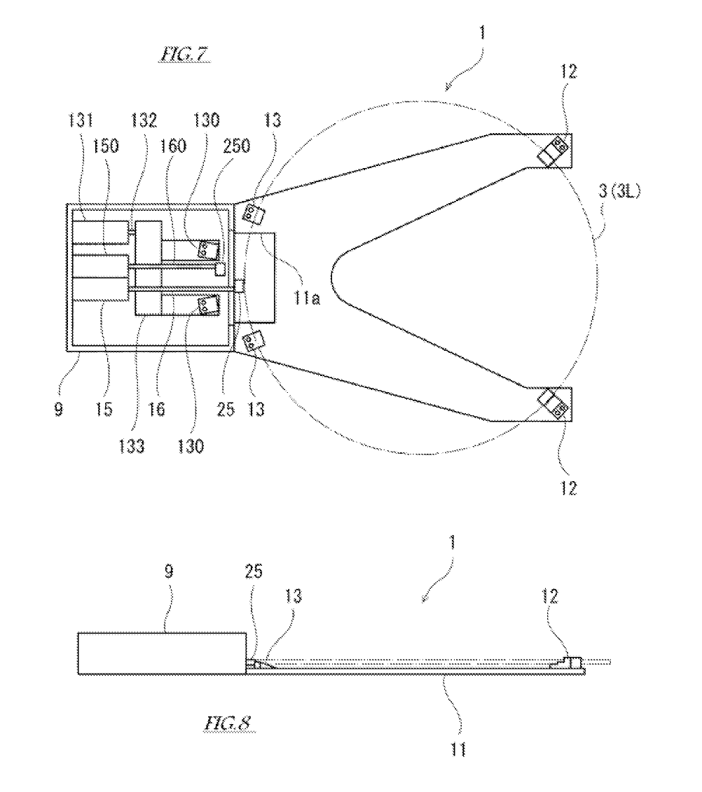

Hereinafter, the substrate transfer hand 1 which is an embodiment of the hand of the present invention will be described in more detail. FIG. 3 is a schematic side view of the substrate transfer hand 1 of FIG. 2. FIG. 4 is a block diagram showing the configuration of the driving system of the substrate transfer hand 1 of FIG. 2. FIG. 5 is a side view of the front guide 12. FIG. 6 is a view taken in the direction of arrows along line VI-VI of FIG. 2.

As shown in FIGS. 2 and 3, the pair of front guides 12 are provided at the tip end portion of the blade 11. The pair of front guides 12 protrude from one of the primary surfaces (upper surface) of the blade 11. Since the pair of front guides 12 have substantially the same structure, one of the front guides 12 will be described below, and description for the other front guide is omitted.

Especially shown in FIG. 5 in detail, each of the front guides 12 has a stepped shape with 3 steps, in a side view. The front guide 12 includes an upper support part 12c and a lower support part 12d. Each of the upper support part 12c and the lower support part 12d has a surface facing in an upward direction, and is able to support the substrate 3 placed thereon. In addition, the front guide 12 includes an upper gripping part 12a and a lower gripping part 12b. Each of the upper gripping part 12a and the lower gripping part 12b has a surface facing the base end of the blade 11. The upper support part 12c and the upper gripping part 12a form a substantially right angle. The edge of the substrate 3 placed on the upper support parts 12c contacts the upper gripping parts 12a. The lower support part 12d and the lower gripping part 12b form a substantially right angle. The edge of the substrate 3 placed on the lower support parts 12d contacts the lower gripping parts 12b.

The height of the upper support part 12c from the surface of the blade 11 is different from the height of the lower support part 12d from the surface of the blade 11. The upper support part 12c is higher than the lower support part 12d. In other words, the upper support part 12c is more distant from the surface of the blade 11 than the lower support part 12d. The upper gripping part 12a is closer to the tip end of the blade 11 than the lower gripping part 12b. Note that the support parts 12c, 12d and the gripping parts 12a, 12b may be provided at one member, or at different members, respectively.

The pair of lower rear guides 13 are provided at the base end side of the blade 11, and face the pair of front guides 12, respectively. Each of the lower rear guides 13 includes a support part facing in the upward direction. This support part includes a portion with a height that is equal to that of the lower support part 12d of the front guide 12.

The pair of upper rear guides 130 are provided at the base end side of the blade 11, and face the pair of front guides 12, respectively. Each of the upper rear guides 130 includes a support part facing in the upward direction. This support part includes a portion with a height that is equal to that of the upper support part 12c of the front guide 12.

The upper rear guides 130 are movable in the forward and rearward direction along the center line L4 of the blade 11. Inside the casing 9, a cylinder 131 as a driving device for the upper rear guides 130 is provided. A rod 132 extending in parallel with the center line L4 is inserted into the cylinder 131 so that the rod 132 is advanceable and retractable. A rear guide support member 133 is connected to the first end portion (output end) of the rod 132. The upper rear guides 130 are secured to the rear guide support member 133.

In a most retracted state, the upper rear guides 130 are located inside the casing 9. In a most advanced state, the upper rear guides 130 are located forward of the opening 9a of the casing 9. In order to avoid interference between the blade 11 and the upper rear guides 130 and the rear guide support member 133 which are advanced in a forward direction from the opening 9a of the casing 9, the blade 11 has an opening 11a. In this opening 11a, the blade 11 does not exist. An object can move through the opening 11a. In the present embodiment, the opening 11a is formed by cutting a portion of the base end portion of the blade 11. However, a formation method of the opening 11a is not limited to this.

The opening 11a is provided over a region which overlaps in the blade normal direction with a portion forward of the opening 9a of the casing 9, of a movement region of the upper rear guides 130. In other words, the movement region of the upper rear guides 130 and the blade 11 do not overlap with each other, in the blade normal direction.

The operation of the upper rear guides 130 is controlled by the controller 8. More specifically, as shown in FIG. 4, an air supply device 18 such as a compressor is connected to the cylinder 131. Between the air supply device 18 and the cylinder 131, a control valve 134 is provided, and controlled by the controller 8. The controller 8 is configured to change the flow rate and direction of air in the control valve 134 so that the rod 132 is extended and the upper rear guides 130 are advanced, or the rod 132 is contracted and the upper rear guides 130 are retracted.

Inside the casing 9, the lower pusher 25 which is advanceable in the forward direction from the casing 9 and a cylinder 15 as a device for driving the lower pusher 25 are provided. The pusher 25 is connected to the first end portion (output end) of a rod 16 of the cylinder 15. The lower pusher 25 has a pushing (pressing) surface facing the tip end of the blade 11. This pushing surface faces the lower gripping parts 12b of the front guides 12. The height of the pushing surface of the pusher 25 from the surface of the blade 11 is set so that the pushing surface can push the edge of the substrate 3 supported by the lower support parts 12d of the front guides 12. More specifically, the height of at least a portion of the lower pusher 25 is set to be equal to the height of the substrate 3 supported by the lower support parts 12d of the front guides 12.

The operation of the lower pusher 25 is controlled by the controller 8. More specifically, as shown in FIG. 4, the air supply device 18 such as the compressor is connected to the cylinder 15. Between the air supply device 18 and the cylinder 15, a control valve 19 is provided, and controlled by the controller 8. The controller 8 is configured to change the flow rate and direction of air in the control valve 19 so that the rod 16 is extended and the lower pusher 25 is advanced, or the rod 16 is contracted and the lower pusher 25 is retracted.

The cylinder 15 is provided with a sensor (not shown) which detects the position of the rod 16. The position of the lower pusher 25 can be found from the detected position of the rod 16. The controller 8 processes the information received from the sensor. Thus, the controller 8 can determine whether or not the substrate 3 is present. Specifically, in a case where the lower pusher 25 is located at a predetermined position where the lower pusher 25 pushes the substrate 3 in a state in which the lower pusher 25 is advanced in the forward direction from the casing 9, the controller 8 can determine that the substrate 3 is placed on the lower support parts 12d. On the other hand, in a case where the lower pusher 25 is located beyond the predetermined position where the lower pusher 25 pushes the substrate 3, the controller 8 can determine that the substrate 3 is not placed on the lower support parts 12d.

Inside the casing 9, the upper pusher 250 which is advanceable in the forward direction from the casing 9 and a cylinder 150 as a device for driving the upper pusher 250 are provided. The upper pusher 250 is connected to the first end portion (output end) of a rod 160 of the cylinder 150. The upper pusher 250 has a pushing (pressing) surface facing the tip end of the blade 11. This pushing surface faces the upper gripping parts 12a of the blade 11. The height of the pushing surface of the pusher 250 from the surface of the blade 11 is set so that the pushing surface can push the edge of the substrate 3 supported by the upper support parts 12c of the front guides 12. More specifically, the height of at least a portion of the upper pusher 250 is set to be equal to the height of the substrate 3 supported by the upper support parts 12c.

The operation of the upper pusher 250 is controlled by the controller 8. More specifically, as shown in FIG. 4, the air supply device 18 such as the compressor is connected to the cylinder 150. Between the air supply device 18 and the cylinder 150, a control valve 190 is provided, and controlled by the controller 8. The controller 8 is configured to change the flow rate and direction of air in the control valve 190 so that the rod 160 is extended and the upper pusher 250 is advanced, or the rod 160 is contracted and the upper pusher 250 is retracted.

The cylinder 150 is provided with a sensor (not shown) which detects the position of the rod 160. The position of the upper pusher 250 can be found from the detected position of the rod 160. The controller 8 processes the information received from the sensor. Thus, the controller 8 can determine whether or not the substrate 3 is present. Specifically, in a case where the upper pusher 250 is located at a predetermined position where the upper pusher 250 pushes the substrate 3 in a state in which the upper pusher 250 is advanced in the forward direction from the casing 9, the controller 8 can determine that the substrate 3 is present. On the other hand, in a case where the upper pusher 250 is located beyond the predetermined position where the upper pusher 250 pushes the substrate 3, the controller 8 can determine that the substrate 3 is not present.

FIG. 6 is a view taken in the direction of arrows along line VI-VI of FIG. 2, of the substrate transfer hand 1 of FIG. 2. In FIG. 6, the constituents other than the blade 11, the pushers 25, 250, and the rear guides 13, 130 are omitted. Dot-and-dash lines of FIG. 6 indicate the substrate 3 supported by the lower support parts 12d of the front guides 12 and the lower rear guides 13 (hereinafter this substrate 3 will be referred to as “lower substrate 3L” in a case where this substrate 3 should be distinguished, and the substrate 3 supported by the upper support parts 12c of the front guides 12 and the upper rear guides 130 (hereinafter this substrate 3 will be referred to as “upper substrate 3U” in a case where this substrate 3 should be distinguished.

As shown in FIG. 6, a position in the blade normal direction of the rear guide support member 133 and a position in the blade normal direction of the blade 11 partially overlap with each other. In other words, the lowermost surface of the rear guide support member 133 is lower than the uppermost surface of the blade 11. In this configuration, as described above, in a case where the rear guides 130 and the rear guide support member 133 are advanced in the forward direction, the rear guides 130 and the rear guide support member 133 move within a range of the opening 11a, i.e., a range in which the rear guides 130 and the rear guide support member 133 do not overlap with the blade 11. Therefore, the rear guide support member 133 does not interfere with the blade 11. This makes it possible to increase the thickness of the rear guide support member 133 and reduce a deformation amount of the rear guide support member 133 in a case where the upper rear guides 130 support the substrate 3. In a case where the rear guide support member 133 and the rear guides 130 are integrated, the lowermost surfaces of the upper rear guides 130 are lower than the uppermost surface of the blade 11.

As shown in FIG. 6, the lower pusher 25 and the upper pusher 250 are provided with a vertical level difference, in the view taken in the direction of arrows along line VI-VI of FIG. 2. The height of the lower pusher 25 may be set so that the lower pusher 25 does not overlap with the upper substrate 3U. The height of the upper pusher 250 may be set so that the upper pusher 250 does not overlap with the lower substrate 3L. In this configuration, the lower pusher 25 does not interfere with the upper substrate 3U, and the lower pusher 25 does not interfere with the lower substrate 3L. Alternatively, the height of the lower pusher 25 may be set so that the lower pusher 25 overlaps with the upper substrate 3U, and the height of the upper pusher 250 may be set so that the upper pusher 250 overlaps with the lower substrate 3L. In this case, as will be described later, the lower pusher 25 does not overlap with the upper substrate 3U and the upper pusher 250 does not overlap with the lower substrate 3L by adjusting the stroke of the lower pusher 25 and the stroke of the upper pusher 250. The stroke of the pusher 25 and the stroke of the pusher 250 mean the movable range of the pusher 25 and the movable rage of the pusher 250, respectively. The stroke of the pusher 25 is defined by a most rearward position and a most forward position of the pusher 25 in the movement of the pusher 25, and the stroke of the pusher 250 is defined by a most rearward position and a most forward position of the pusher 250 in the movement of the pusher 250.

[Operation of Substrate Transfer Hand 1]

Now, the operation of the substrate transfer hand 1 with the above-described configuration will be described. The operations of the upper rear guides 130, the lower pusher 25, and the upper pusher 250, which will be described below, are realized by the actions of the corresponding cylinders 131, 15, and 150, respectively, which are controlled by the controller 8, although this is not described in detail.

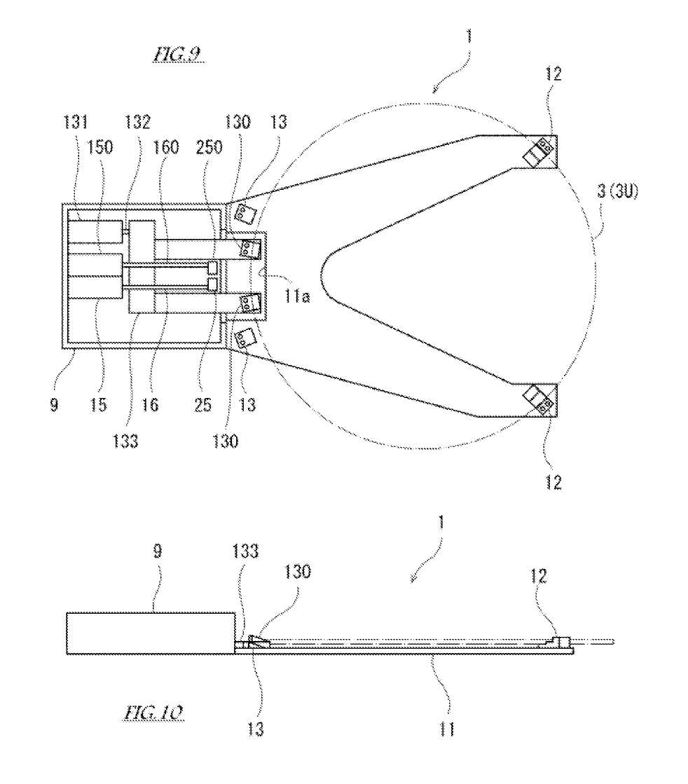

In FIGS. 2 and 3, the substrate 3 (3L) supported by the lower support parts 12d of the pair of front guides 12 and the lower rear guides 13 is indicated by dot-and-dash line. This substrate 3 is, for example, the contaminated substrate 3. In this case, the upper rear guides 130, the lower pusher 25, and the upper pusher 250 are retracted from the substrate 3 and do not interfere with the substrate 3. In a case where the lower pusher 25 is advanced in this state, the substrate 3 supported by the lower support parts 12d of the front guides 12 and the lower rear guides 13 is pushed in the forward direction by the lower pusher 25. In the meantime, the front edge of the substrate 3 contacts the pair of lower gripping parts 12b. In this way, the edge of the substrate 3 is pushed (pressed) by the pair of lower gripping parts 12b and the lower pusher 25 at three points. In this state, the substrate 3 is gripped by the substrate transfer hand 1 (see FIGS. 7 and 8).

After the advancement motion of the lower pusher 25 begins, the controller 8 monitors a detection signal from the sensor (not shown) which detects the position of the lower pusher 25. In the state of FIGS. 7 and 8, the lower pusher 25 is located at the predetermined position where the lower pusher 25 pushes the substrate 3, and thus the controller 8 determines that the lower substrate 3 (3L) is placed on the blade 11.

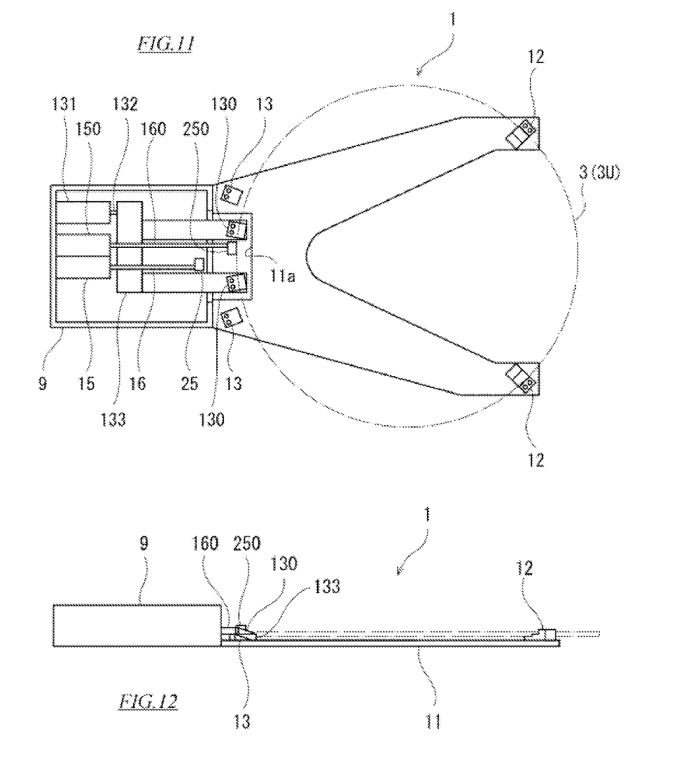

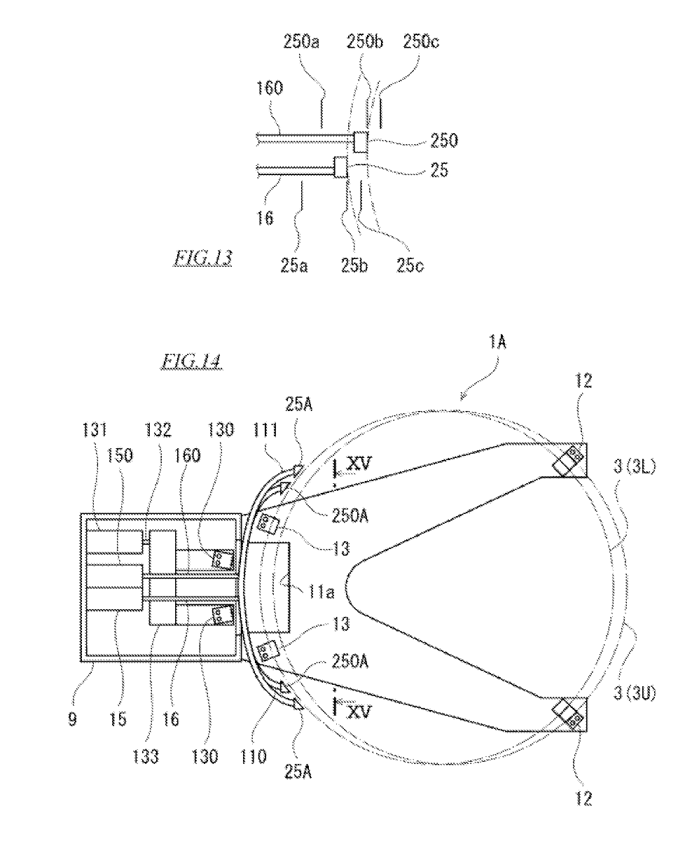

In FIGS. 9 and 10, the substrate 3 (3U) supported by the upper support parts 12c of the pair of front guides 12 and the upper rear guides 130 is indicated by dot-and-dash line. This substrate 3 is, for example, the clean substrate 3. The upper rear guides 130 are in an advanced position where the upper rear guides 130 can support the substrate 3. The lower pusher 25, and the upper pusher 250 are retracted from the edge of the substrate 3 and do not interfere with the substrate 3. In a case where the upper pusher 250 is advanced in this state, the substrate 3 supported by the upper support parts 12c of the front guides 12 and the upper rear guides 130 is pushed in the forward direction by the upper pusher 250. In the meantime, the front edge of the substrate 3 contacts the pair of upper gripping parts 12a. In this way, the edge of the substrate 3 is pushed (pressed) by the pair of upper gripping parts 12a and the upper pusher 250 at three points. In this state, the substrate 3 is gripped by the substrate transfer hand 1 (see FIGS. 11 and 12).

After the advancement motion of the upper pusher 250 begins, the controller 8 monitors a detection signal from the sensor (not shown) which detects the position of the upper pusher 250. In the state of FIGS. 11 and 12, the upper pusher 250 is located at the predetermined position where the upper pusher 250 pushes the substrate 3, and thus, the controller 8 determines that the upper substrate 3 (3U) is placed on the blade 11.

As described above, the contaminated substrate 3 is supported by the lower support parts 12d of the pair of front guides 12 and the lower rear guides 13 and gripped by the lower gripping parts 12b of the pair of front guides 12 and the lower pusher 25. Also, the clean substrate 3 is supported by the upper support parts 12c of the pair of front guides 12 and the upper rear guides 130, and gripped by the upper gripping parts 12a of the pair of front guides 12 and the upper pusher 250. Since the support parts and the gripping parts which are used to support and grip the substrate 3 are made different between the contaminated substrate 3 and the clean substrate 3, it becomes possible to prevent a situation in which the substrate transfer hand 1 is contaminated by the contaminated substrate 3 and the clean substrate 3 held by the contaminated substrate transfer hand 1 is contaminated. In a case where the contaminated substrate and the clean substrate are held by the substrate transfer hand 1 with a vertical level difference, it is desirable to hold the clean substrate at a higher vertical level. This is because contaminant falls down by an air flow called a down flow for keeping a clean environment.

[Strokes of Pushes 25, 250]

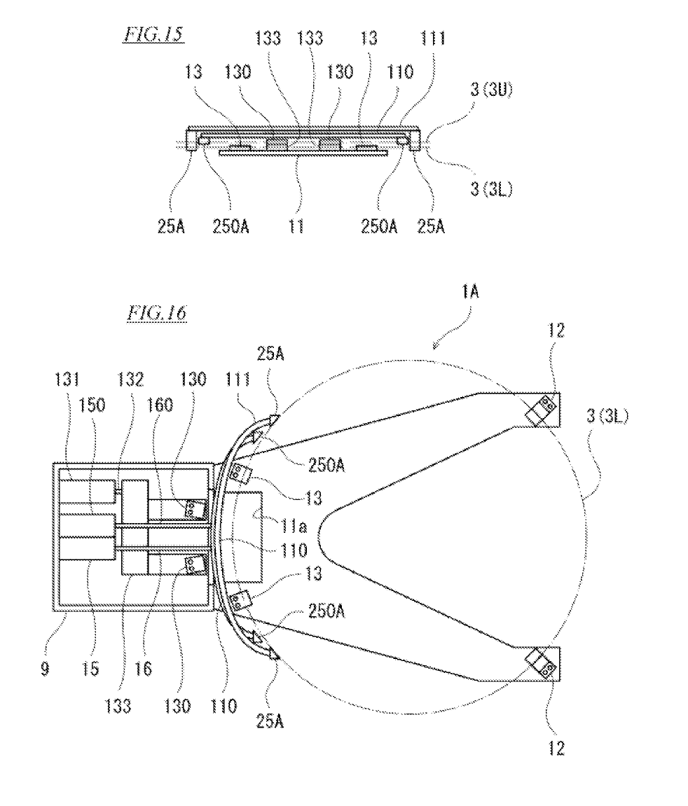

The strokes of the pushes 25, 250 will be described with reference to FIG. 13 in detail. FIG. 13 is a view for explaining the stroke of the lower pusher 25 and the stroke of the upper pusher 250.

The stroke of the lower pusher 25 is adjusted depending on a distance for which the rod 16 of the cylinder 15 is advanced or retracted, a relation between the location of the substrate 3 which is gripped by the substrate transfer hand 1 and the mounting location of the cylinder 15, the mounting location of a stopper (not shown) which is provided as necessary, and adjusts the stroke of the lower pusher 25, the location of the lower pusher 25 which is mounted on the rod 16, and the like. In contrast, the stroke of the upper pusher 250 is adjusted depending on a distance for which the rod 160 of the cylinder 150 is advanced or retracted, a relation between the location of the substrate 3 which is gripped by the substrate transfer hand 1 and the mounting location of the cylinder 150, the mounting location of a stopper (not shown) which is provided as necessary, and adjusts the stroke of the upper pusher 250, the location of the upper pusher 250 which is mounted on the rod 160, and the like.

Hereinafter, one of coordinates of an application point in a case where the lower pusher 25 pushes the lower substrate 3L will be referred to as “25 point” and one of coordinates of an application point in a case where the upper pusher 250 pushes the upper substrate 3U will be referred to as “250 point”. In FIG. 13, the position 25a indicates the position of 25 point of the state in which the lower pusher 25 is most retracted, the position 25b indicates the position of 25 point of the state in which the lower substrate 3L is placed on the blade 11 and the lower pusher 25 pushes the lower substrate 3L, and the position 25c indicates the position of 25 point of the state in which the lower substrate 3L is not placed on the blade 11 and the lower pusher 25 is most advanced. Also, in FIG. 13, the position 250a indicates the position of 250 point of the state in which the upper pusher 250 is most retracted, the position 250b indicates the position of 250 point of the state in which the upper substrate 3U is placed on the blade 11 and the upper pusher 250 pushes the upper substrate 3U, and the position 250c indicates the position of 250 point of the state in which the upper substrate 3U is not placed on the blade 11 and the upper pusher 250 is most advanced.

In the present embodiment, the stroke of the lower pusher 25 is set so that the lower pusher 25 is located rearward of the upper substrate 3U in a state in which 25 point is at the position 25c. More specifically, the stroke of the lower pusher 25 is set so that the lower pusher 25 does not interfere with the forward substrate 3 of the two substrates 3 held by the substrate transfer hand 1 with a position difference in the forward and rearward direction (and in the vertical direction) between the two substrates 3, in a state in which the lower pusher 25 is most advanced. With this setting, it becomes possible to avoid interference between the lower pusher 25 and the forward substrate 3 of the two substrates 3 held by the substrate transfer hand 1 with a position difference in the forward and rearward direction, irrespective of the position of the lower pusher 25.

The stroke of the upper pusher 250 is set so that the upper pusher 250 is located rearward of the lower substrate 3L in a state in which 250 point is at the position 250a. More specifically, the stroke of the upper pusher 250 is set so that the upper pusher 250 does not interfere with the rearward substrate 3 of the two substrates 3 held by the substrate transfer hand 1 with a position difference in the forward and rearward direction (and in the vertical direction) between the two substrates 3, in a state in which the upper pusher 250 is most retracted. With this setting, it becomes possible to avoid interference between the upper pusher 250 and the rearward substrate 3 of the two substrates 3 held by the substrate transfer hand 1 with a position difference in the forward and rearward direction, in a state in which the upper pusher 250 is most retracted.

As described above, the substrate transfer hand 1 according to the present embodiment includes the casing 9, the blade 11 with a thin plate shape, the base end portion of which is joined to the casing 9, the pair of front guides 12 provided at the tip end portion of the blade 11 and including the lower support parts (first support parts) 12d and the upper support parts (second support parts) 12c which support the substrates 3, the lower support parts 12d and the upper support parts 12c being different in height from the blade 11, the lower rear guides (first rear guides) 13 provided at the base end portion of the blade 11 and each having a portion with a height from the blade 11 that is equal to that of corresponding one of the lower support parts 12d of the front guides 12, the upper rear guides (second rear guides) 130 provided at the base end side of the blade 11 and each having a portion with a height from the blade 11 that is equal to that of corresponding one of the upper support parts 12c of the front guides 12, and the cylinder (driving device) 131 which is provided inside the casing 9, has an output end which is advanceable and retractable with respect to the substrate supported by the blade 11, and moves the upper rear guides 130 coupled to the output end within a region where the upper rear guides 130 do not overlap with the blade 11 in the blade normal direction.

The transfer robot 2 according to the present embodiment includes the arm 40, and the substrate transfer hand 1 mounted on the tip end portion of the arm 40.

In the substrate transfer hand 1 and the transfer robot 2 including the substrate transfer hand 1, the upper rear guides 130 provided at the base end side of the substrate transfer hand 1 are advanced and retracted with respect to the substrate 3 supported by the blade 11, and the cylinder 131 which is the driving device for driving the upper rear guides 130 is accommodated in the casing 9. In other words, the upper rear guides 130 and the driving device are disposed collectively at the base end portion of the substrate transfer hand 1. Since the upper rear guides 130 are movable within the region where the upper rear guides 130 do not overlap with the blade 11 in the blade normal direction, the upper rear guides 130 and the driving device can be disposed so that they do not interfere with the blade 11. This makes it possible to avoid reduction of a strength of the blade 11 which may be caused by providing the upper rear guides 130 and the driving device for driving the upper rear guides 130. In brief, the blade 11 has a proper strength, and the stability of the operation of the substrate transfer hand 1 is not degraded.

In the substrate transfer hand 1 according to the above-described embodiment, the height of the lower support parts (first support parts) 12d from the blade 11 is lower than the height of the upper support parts (second support parts) 12c from the blade 11.

The fact that the lower support parts 12d are lower than the upper support parts 12c means that the lower rear guides 13 are lower than the upper rear guides 130. In the substrate transfer hand 1 with the above-described configuration, the upper rear guides 130 can be retracted from the substrate 3 in a state in which the substrate 3 is supported by the cooperation of the lower rear guides 13 and the lower support parts 12d. In other words, the upper rear guides 130 can be located apart from the contaminant. The contaminant falls downward. By placing the rear guides (upper rear guides 130) which can be located apart from the contaminant at an upper side and the lower rear guides 13 at a lower side, cleanliness of the rear guides (upper rear guides 130) located at an upper side can be increased. In the substrate transfer hand 1, the contaminated substrate 3 may be supported by the lower rear guides 13 and the lower support parts 12d, and the clean substrate 3 may be supported by the upper rear guides 130 and the upper support parts 12c.

### Modified Example 1

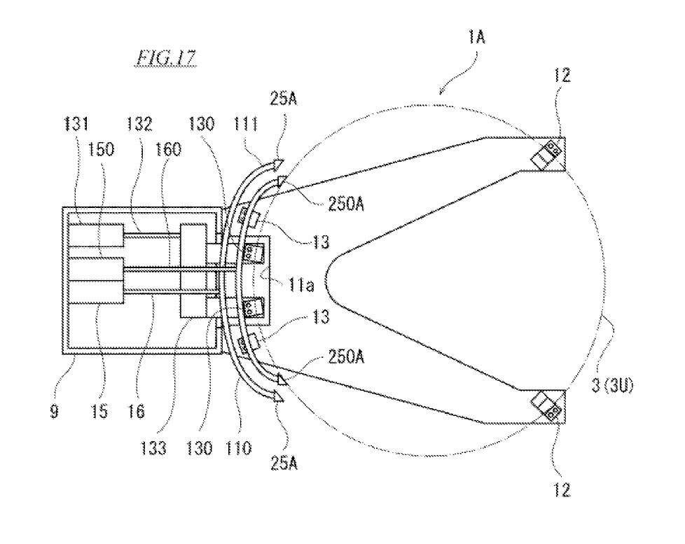

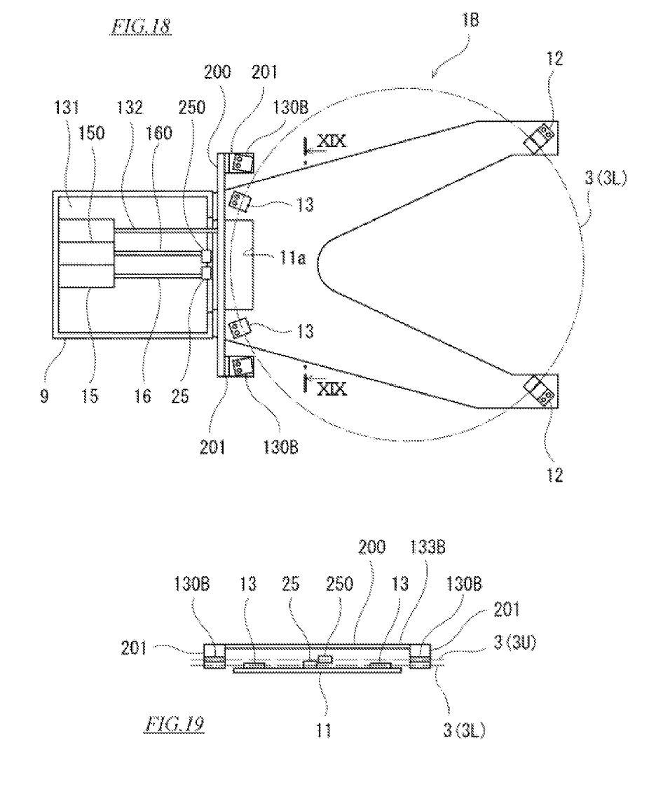

Next, Modified Example 1 of the above-described embodiment will be described with reference to FIGS. 14 to 17. FIG. 14 is an enlarged plan view of a substrate transfer hand 1A according to Modified Example 1. FIG. 15 is a view taken in the direction of arrows along line XV-XV of FIG. 14. FIG. 16 is a plan view showing a state in which the substrate transfer hand 1A of FIG. 14 is gripping the lower substrate 3L. FIG. 17 is a plan view showing a state in which the substrate transfer hand 1A of FIG. 14 is gripping the upper substrate 3U. In description of Modified Example 1, the same or corresponding members as those of the above-described embodiment are designated by the same reference symbols and will not be described in repetition.

The configuration of the substrate transfer hand 1A according to Modified Example 1 is substantially the same as that of the substrate transfer hand 1 according to the above-described embodiment except the configurations of the lower pusher 25 and the upper pusher 250. Therefore, hereinafter, the configurations of lower pushers 25A and upper pushers 250A of the substrate transfer hand 1A according to Modified Example 1 will be described in detail, and description of the other constituents is omitted.

The pair of lower pushers 25A are provided at the base end side of the blade 11. The pair of lower pushers 25A are disposed symmetrically with respect to the center line L4 of the blade 11. The pair of lower pushers 25A are mounted on the both end portions of a pusher support member 111 extending in a circular-arc shape in a direction perpendicular to the center line L4 of the blade 11. The center portion of the pusher support member 111 is coupled to the tip end portion of the rod 16.

The pair of upper pushers 250A are provided at the base end side of the blade 11. The pair of upper pushers 250A are disposed symmetrically with respect to the center line L4 of the blade 11. The pair of upper pushers 250A are mounted on the both end portions of a pusher support member 110 extending in the circular-arc shape in the direction perpendicular to the center line L4 of the blade 11. The center portion of the pusher support member 110 is coupled to the tip end portion of the rod 160.

A distance from each of the upper pushers 250A to the center line L4 of the blade 11 is shorter than a distance from each of the lower pushers 25A to the center line L4 of the blade 11. In other words, in a case where the center line L4 is the center, the pair of upper pushers 250A are located inward of the pair of lower pushers 25A. The distances from the pushers 25A, 250A to the center line L4 of the blade 11 are longer than distances from the rear guides 13, 130 to the center line L4 of the blade 11. In other words, in a case where the center line L4 is the center, the pushers 25A, 250A are located outward of the rear guides 13, 130.

The height of the pusher support member 111 from the surface of the blade 11 and the height of the pusher support member 110 from the surface of the blade 11 are higher than the height of the lower rear guides 13 from the surface of the blade 11 and the height of the upper rear guides 130 from the surface of the blade 11. The pair of lower pushers 25A are mounted on the pusher support member 111 and extend downward from the pusher support member 111. The pair of lower pushers 25A have pushing (pressing) surfaces, respectively, facing the tip end of the blade 11. The pushing surfaces are at a level equal to that of the lower gripping parts 12b of the front guides 12 and face the lower gripping parts 12b. The pair of upper pushers 250A are mounted on the pusher support member 110 and extend downward from the pusher support member 110. The pair of upper pushers 250A have pushing (pressing) surfaces, respectively, facing the tip end of the blade 11. The pushing surfaces are at a level equal to that of the upper gripping parts 12a of the blade 11 and face the upper gripping parts 12a. Note that the pushers 25A, 250A are located higher than the bottom surface of the blade 11. In this configuration, in a case where another substrate transfer hand 1 (not shown) is provided under the substrate transfer hand 1A to construct the transfer robot 2 with a double-hand configuration, interference between the two substrate transfer hands 1 can be prevented.

As described above, since the edge of the substrate 3 is pushed (pressed) by the pushers 25A or 250A at two points, the substrate 3 can be more stably pushed. Since each of the pusher support members 111, 110 is an elongated member, the pusher support member 111 or 110 is elastically deformed and the substrate 3 is more flexibly gripped, in a case where the substrate 3 is pushed by the pushers 25A or 250A.

### Modified Example 2

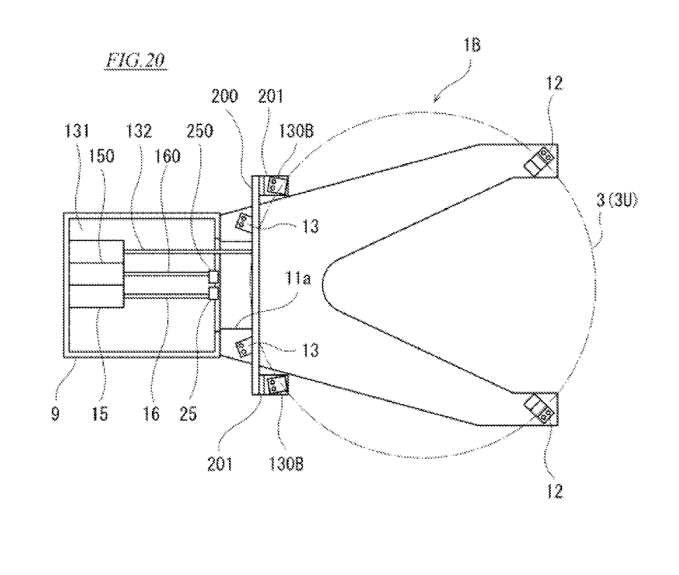

Next, Modified Example 2 of the above-described embodiment will be described with reference to FIGS. 18 to 20. FIG. 18 is an enlarged plan view of a substrate transfer hand 1B according to Modified Example 2. FIG. 19 is a view taken in the direction of arrows along line XIX-XIX of FIG. 18. FIG. 20 is a plan view showing a state in which the substrate transfer hand 1B of FIG. 18 is gripping the upper substrate 3U. In description of Modified Example 2, the same or corresponding members as those of the above-described embodiment are designated by the same reference symbols and will not be described in repetition.

The configuration of the substrate transfer hand 1B according to Modified Example 2 is substantially the same as that of the substrate transfer hand 1 according to the above-described embodiment except the placement and configuration of the upper rear guides 130 and the rear guide support member 133. Therefore, hereinafter, the configurations of upper rear guides 130B and a rear guide support member 133B of the substrate transfer hand 1B according to Modified Example 2 will be described in detail, and description of the other constituents is omitted.

In the substrate transfer hand 1 according to the above-described embodiment, in a case where the center line L4 is the center, the pair of upper rear guides 130 are disposed inward of the pair of lower rear guides 13, respectively. In contrast, in the substrate transfer hand 1B according to Modified Example 2, in a case where the center line L4 is the center, the pair of upper rear guides 130B are disposed outward of the pair of lower rear guides 13, respectively. In addition, the pair of upper rear guides 130B are disposed outward of the blade 11.

To realize the above-described configuration, in the present modified example, the rear guide support member 133B is provided between the rod 132 of the cylinder 131 and the upper rear guides 130. The rear guide support member 133B is a member which serves to hold (keep) the upper rear guides 130 at locations that are outside a region where the upper rear guides 130 overlap with the blade 11 in the blade normal direction (at locations that are on lateral sides (rightward and leftward) of the blade 11 in the present modified example).

The rear guide support member 133B includes a first member 200 extending in a direction perpendicular to the center line L4 of the hand body, and second members 201 coupled to the both ends of the first member 200. The first member 200 extends to locations that are outward of the blade 11, on both sides of the center line L4 of the hand body. The first member 200 is connected to the rod 132 so that the first member 200 is higher than the lower pusher 25, the upper pusher 250, and the lower rear guides 13. Each of the second members 201 has a L-shape formed by a vertical part joined to the first member 200 and a horizontal part to which the upper rear guide 130B is mounted. The upper rear guides 130B mounted on the second members 201 have support parts, respectively, facing in the upward direction. Each of the support parts has a portion with a height that is equal to that of corresponding one of the upper support parts 12c of the front guides 12.

The position in the blade normal direction, of at least a portion of the upper rear guides 130B or the second members 201 of the rear guide support member 133B may overlap with the position in the blade normal direction, of the blade 11. In other words, at least a portion of the upper rear guides 130B or the second members 201 of the rear guide support member 133B may be at a level equal to that of the blade 11. In this configuration, the thickness of the substrate transfer hand 1 including the rear guide support member 133B is not increased. This is useful in a case where the substrate transfer hand 1 includes a plurality of hands.

The upper rear guides 130B with the above-described configuration are advanced and retracted along the center line L4 of the blade 11. In a case where the upper rear guides 130B are advanced, the upper rear guides 130B and the rear guide support member 133B are movable within a range where the upper rear guides 130B and the rear guide support member 133B do not overlap with the blade 11 in the blade normal direction. The operation of the upper rear guides 130B is realized by the action of the cylinder 131 controlled by the controller 8 as in the above-described embodiment.

So far, the preferred embodiment (and Modified Examples 1, 2) of the present invention have been described. The above-described configurations can be modified as follows, for example.

Although in the above-described embodiment, the blade 11 has a Y-shape when viewed from the blade normal direction, the blade 11 need not have the forked (branched) portions at the tip end side. Further, the blade 11 may include a plurality of members.

Although in the above-described embodiment, the upper rear guides 130 and the rear guide support member 133 are separate members, the upper rear guides 130 and the rear guide support member 133 may be integrated. Other members may be provided between the upper rear guides 130 and the rear guide support member 133. Further, the upper rear guides 130 may be directly provided at the rod 132 of the cylinder 131. In brief, any configuration may be used so long as the motion of the rod 132 of the air cylinder 131 is transmitted to the upper rear guides 130, and the rear guides 130 are disposed at proper locations.

Although in the above-described Modified Example 1, the pushers 25A and the pusher support member 111 are separate members and the pushers 250A and the pusher support member 110 are separate members, the pushers 25A and the pusher support member 111 may be integrated and the pushers 250A and the pusher support member 110 may be integrated. Other members may be provided between the pushers 25A and the pusher support member 111 and between the pushers 250A and the pusher support member 110. In brief, any configuration may be used so long as the motions of the rods 16, 160 of the air cylinders 15, 150 are transmitted to the pushers 25A, 250A and the pushers 25A, 250A are disposed at proper locations.

In the above-described embodiment, the pushers 25, 250 and the rear guides 130 may be moved by a movement means other than the cylinder and the rod. The movement direction of the output end of the movement means which moves the pushers 25, 250 and the rear guides 130 is not limited to the forward and rearward direction of the blade 11 and may be any direction so long as the output end of the movement means is advanceable and retractable with respect to the substrate 3 supported by the blade 11. The movement path of the output end of the movement means which moves the pushers 25, 250 and the rear guides 130 is not limited to a straight line and may be a circle, a curve, or a combination of these.

Numerous modifications and alternative embodiments of the present invention will be apparent to those skilled in the art in view of the foregoing description. Accordingly, the description is to be construed as illustrative only, and is provided for the purpose of teaching those skilled in the art the best mode of conveying out the invention. The details of the structure and/or function may be varied substantially without departing from the spirit of the invention.

### REFERENCE SIGNS LIST

1, 1A, 1B substrate transfer hand
2 transfer robot
3, 3L, 3U substrate
8 controller
9 casing
11 blade
11a opening
12 front guide
12a upper gripping part
12b lower gripping part
12c upper support part
12d lower support part
13 lower rear guide
15 cylinder
16 rod
18 air supply device
19 control valve
25, 25A lower pusher
110 pusher support member
111 pusher support member
130 upper rear guide
131 cylinder (driving device)
132 rod
133, 133B rear guide support member
150 cylinder
160 rod
250, 250A upper pusher

1. A substrate transfer hand comprising:
a casing;
a blade with a thin plate shape, the blade having a base end portion coupled to the casing;
a front guide provided at a tip end portion of the blade, and including a first support part and a second support part which support a substrate, the first support part and the second support part being different in height from the blade;
a first rear guide provided at the base end portion of the blade, and having a portion with a height from the blade that is equal to a height from the blade, of the first support part of the front guide;
a second rear guide provided at a base end side of the blade, and having a portion with a height from the blade that is equal to a height from the blade, of the second support part of the front guide; and
a driving device provided inside the casing, and having an output end which is advanceable and retractable with respect to the substrate supported by the blade, the driving device being configured to move the second rear guide coupled to the output end within a region where the second rear guide does not overlap with the blade in a normal direction of the blade.

2. The substrate transfer hand according to claim 1,
wherein the height of the first support part from the blade is lower than the height of the second support part from the blade.

3. The substrate transfer hand according to claim 1,
wherein the blade has an opening provided over a region which overlaps with a movement region of the second rear guide in the normal direction of the blade.

4. The substrate transfer hand according to claim 1, comprising:
a rear guide support member provided between the driving device and the second rear guide, the rear guide support member being configured to hold the second rear guide at a location that is outside a region where the second rear guide overlaps with the blade in the normal direction of the blade.

5. The substrate transfer hand according to claim 4,
wherein a position in the normal direction of the blade, of at least a portion of the second rear guide or the rear guide support member, overlaps with a position in the normal direction of the blade, of the blade.

6. A robot comprising:
an arm; and
the substrate transfer hand as recited in claim 1, the substrate transfer hand being mounted on a tip end portion of the arm.
